(19) United States
(12) Patent Application Publication
(10) Pub. No.: US 2002/0121699 A1
(43) Pub. Date: Sep. 5, 2002

(54) Dual damascene Cu contact plug using selective tungsten deposition

(76) Inventors: Kuan-Lun Cheng, Kao-Hsiung City (TW); Tony Lin, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/795,305

(22) Filed: Mar. 1, 2001

(51) Int. Cl. H01L 23/48; H01L 23/52; H01L 29/40

(52) U.S. Cl. 257/758

(57) ABSTRACT

A dual damascene Cu contact plug is provided which has a layer of selective tungsten formed between the dual damascene Cu contact plug and a source, drain, or gate electrode of a MOS transistor formed on a fully-depleted SOI substrate. The layer of selective tungsten is formed by using a selective W deposition and comprises of a WN/W composite to prevent the diffusion of copper atoms into the underlying silicon substrate.

### BACKGROUND OF THE INVENTION

1.Field of the Invention

The present invention relates to a Cu contact plug, and more particularly, to a dual damascene Cu contact plug formed on a silicon-on-insulator (SOI).

2.Description of the Prior Art

A Cu contact plug is used to electrically connect a source, drain, and gate electrodes of a MOS transistor with a metal layer in a multilevel metallization process. In the prior art, tungsten (W) of low conductivity is used as a contact plug of the first level, that is, the surface of the silicon substrate since copper has a high conductivity and is apt to diffuse into the silicon materials or the oxide layers to influence the characteristics of the semiconductor devices.

Please refer to FIG. 1 to FIG. 4. FIG. 1 to FIG. 4 are schematic diagrams of the process of forming a W plug and an aluminum (Al) wire on a fully-depleted SOI substrate according to the prior art. As shown in FIG. 1, the fully-depleted SOI substrate 10 comprises a supporting substrate 11, an insulating layer 12 formed on the supporting substrate 11, a silicon layer 13 of approximately 0.1˜0.3 μm thickness, and a plurality of MOS transistors 14 formed on the substrate 10 (only one shown in FIG. 1). The MOS transistor 14 comprises a source 14s, a drain 14d, and a gate electrode 14g. In the prior art, a CoSi₂ layer 15s, 15d, 15g covers the 14s, 14d, 14g, followed by the deposition of an inter-layer dielectric (ILD) 16. Then, a photoresist layer 18 is coated on the ILD layer 16.

A photolithographic process is performed to transfer the pattern of the W plug to the photoresist layer 18. As shown in FIG. 2, an etching process is then performed using the patterned photoresist layer 18 as a hard mask so that the ILD layer 16 uncovered by the photoresist layer 18 is anisotropically etched down to the surface of the source 14s, the drain 14d, or the gate 14g to form a contact plug hole 17 (in FIG. 2 the contact plug hole is connected with the source 14s). Then, as shown in FIG. 3, after the photoresist layer 18 is removed, a glue layer 21 comprised of titanium nitride (TiN) or titanium tungsten (TiW) is formed. Thereafter, a low pressure chemical vapor deposition process (LPCVD) is performed to deposit a tungsten layer 22. The thickness of the glue layer 21 is approximately 500˜1000 angstroms (Å), and the thickness of the tungsten layer 22 is approximately 5000˜10000 Å.

As shown in FIG. 4, a chemical mechanical polishing process (CMP) is then performed to remove the residual tungsten layer 22 to form a W plug 20, followed by a process of forming a plurality of interconnects 24. In the prior art, the interconnects 24 are comprised of Al alloy. In the process of forming the interconnects 24, a barrier layer 23 is deposited to prevent direct contact between the interconnect 24 and the W plug 20. Next, a DC sputtering process is performed to deposit an Al alloy layer 26, and an anti-reflection layer 28 on the Al alloy layer 26. Finally, a photo-etching-process (PEP) is performed to define and form a plurality of the interconnects 24 (only one shown in FIG. 4)

However, three defects occur in the prior art:

(1) Numerous Si atoms are consumed during the formation of the CoSi₂ layers 15s/d/g on the source 14s, the drain 14d, and the gate 14g. As a result, the leakage current of the shallow junction is affected as well as causing voids in the silicon layer 13, which has an approximate thickness of 0.1˜0.3 μm;

(2) The conductivity of the W plug 20 is lower than that of the Cu plug, and consequently, the speed of signal transportation is delayed and the resistance of the inter-connect is greater;

(3) In the prior art, many complicated processes are required, such as the addition of both the barrier layer 23 and the anti-reflection layer 28, resulting in inefficiency.

### SUMMARY OF THE INVENTION

It is an object of the present invention to provide a dual damascene Cu contact plug formed on a fully-depleted SOI substrate to solve the above-mentioned problems.

The present invention provides a Cu contact plug. The Cu contact plug and a Cu wire are simultaneously formed in a dual damascene structure of an inter-layer dielectric to electrically connect the Cu wire with a source, drain, or gate electrode of a MOS transistor formed on a fully-depleted SOI substrate. A layer of selective tungsten is formed between the Cu contact plug and the source, drain, or gate electrode. The layer of selective tungsten is comprised of a WN/W composite to prevent the diffusion of copper atoms into the underlying silicon substrate.

It is an advantage of the present invention that the layer of selective tungsten is used to prevent both the leakage current of the shallow junction and voids.

It is the other advantage of the present invention to simplify the complicated process by simultaneously forming both the Cu contact plug and the Cu wire.

It is another advantage of the present invention that the resistance of the inter-connect is lower and the speed of signal transportation is faster.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1 to FIG. 4 are schematic diagrams of the processes of forming the W plug and the Cu wire according to the prior art.

FIG. 5 to FIG. 14 are schematic diagrams of the process of forming the dual damascene Cu contact plug according to the present invention.

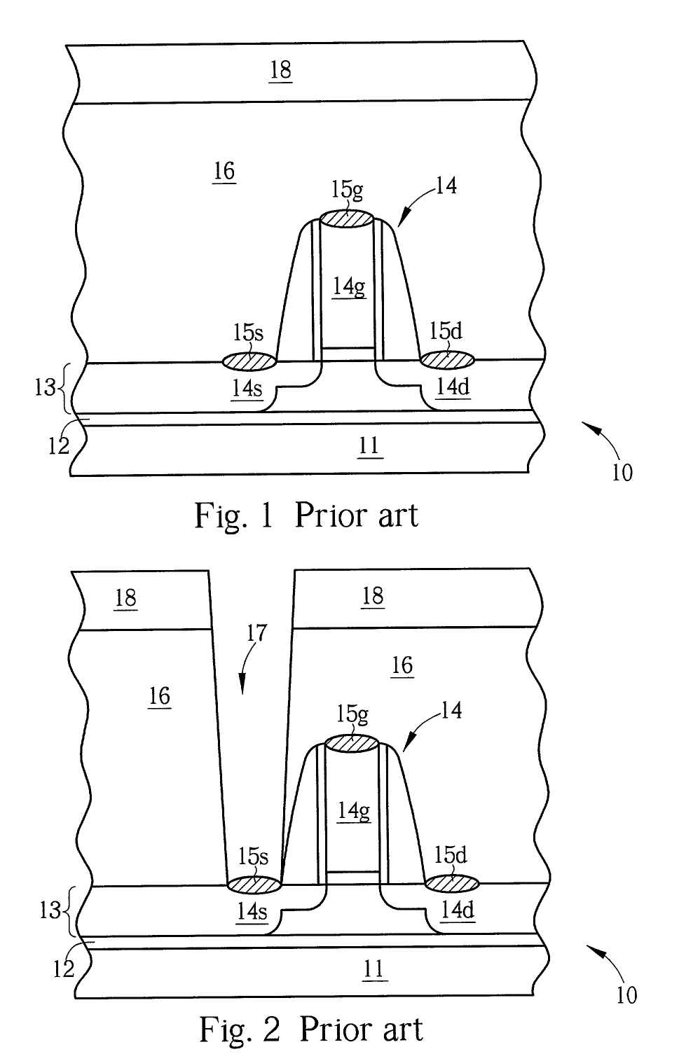

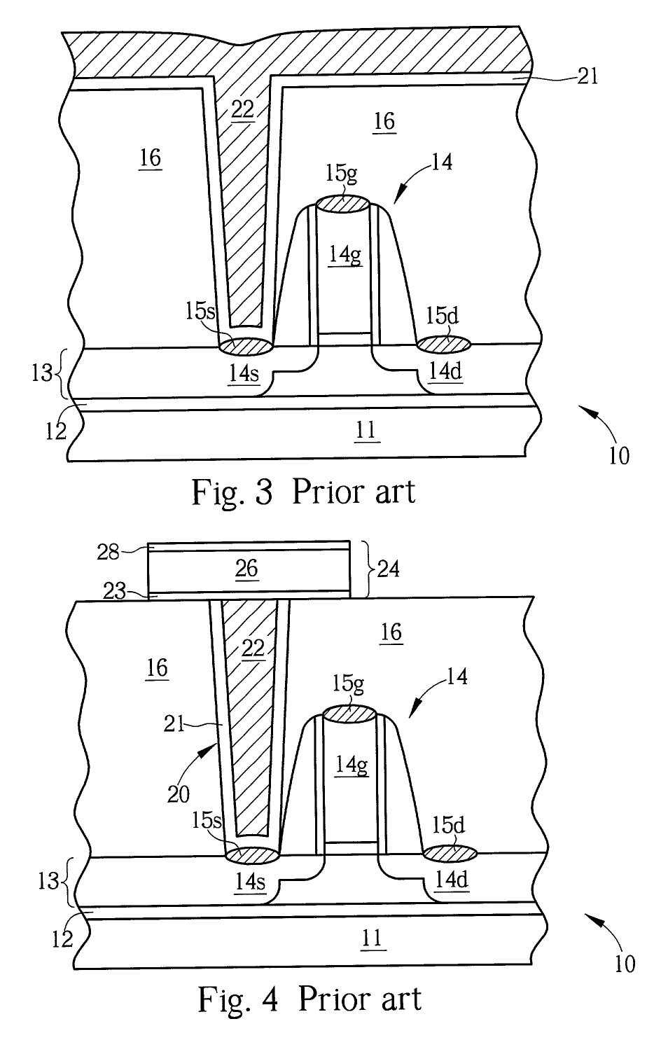

### DETAILED DESCRIPTION OF THE PREFERRED EMBODIMENT

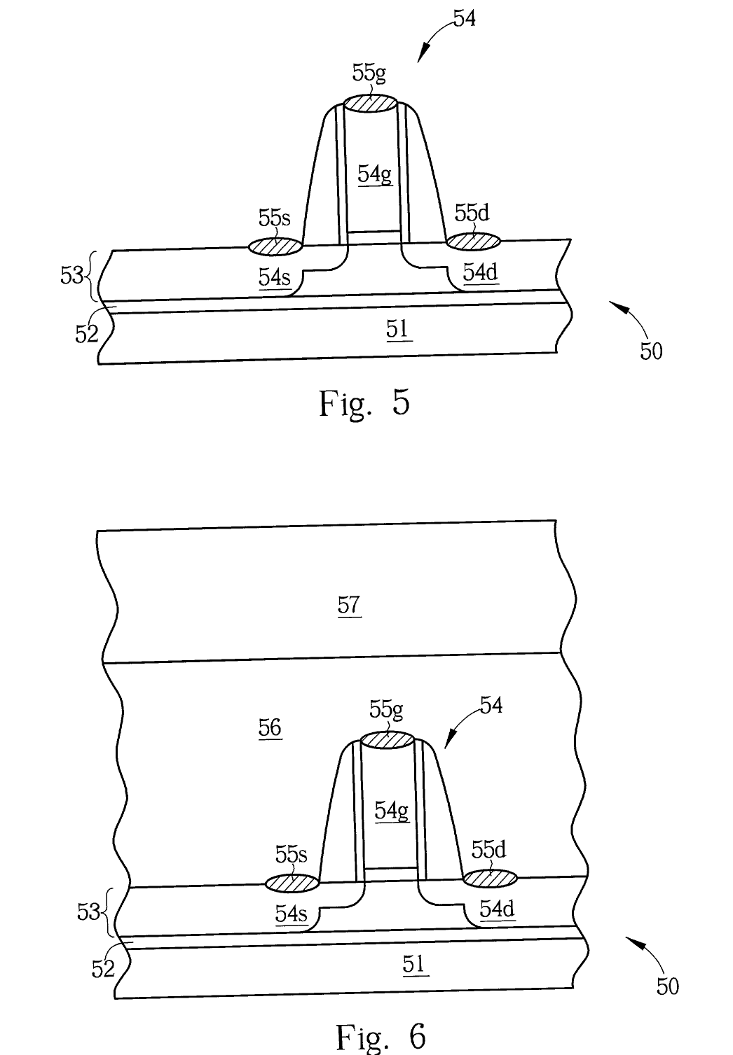

Please refer to FIG. 5 to FIG. 14 of the schematic diagrams of the process of forming a dual damascene Cu contact plug 70 on a fully-depleted SOI substrate 50 according to the present invention. As shown in FIG. 5, the fully-depleted SOI substrate 50 comprises a supporting substrate 51, an insulating layer 52, and silicon layer 53 with an approximate thickness of 0.1˜0.3 μm, respectively. A plurality of MOS transistors 54 is formed on the substrate 10 (only one shown in FIG. 5), and the MOS transistor 54 comprises a source 54s, a drain 54d, and a gate electrode 54g.

In the present invention, a selective W deposition is performed by a silicon reduction reaction that uses tungsten hexafluoride (WF₆) gas to react with the silicon of the source 54s, the drain 54d, and the gate electrode 54g of the MOS transistor 54. Then, each selective tungsten layer 55s, 55d, 55g is selectively deposited on the source 54s, the drain 54d, and the gate electrode 54g using the silicon reduction reaction. The silicon reduction reaction is expressed as the following:

2WF₆+3Si→2W+3SiF₄

Additionally, a tungsten nitride (WN) layer (not shown) is formed on the selective tungsten layers 55s, 55d, 55g so that the selective tungsten layers 55s, 55d, 55g is comprised of a WN/W composite.

As shown in FIG. 6, a first ILD 56 is then deposited on the silicon layer 53, followed by the deposition of a second ILD 57 on the first ILD 56. The first ILD 56 and the second ILD 57 are both comprised of silicon oxide formed by a plasma enhanced chemical vapor deposition (PECVD) process to deposit a phosphosilicate glass (PSG). Additionally, the first ILD 56 has an etching selectivity that is different from the second ILD 57, which is due to the different densities of the first ILD 56 and the second ILD 57.

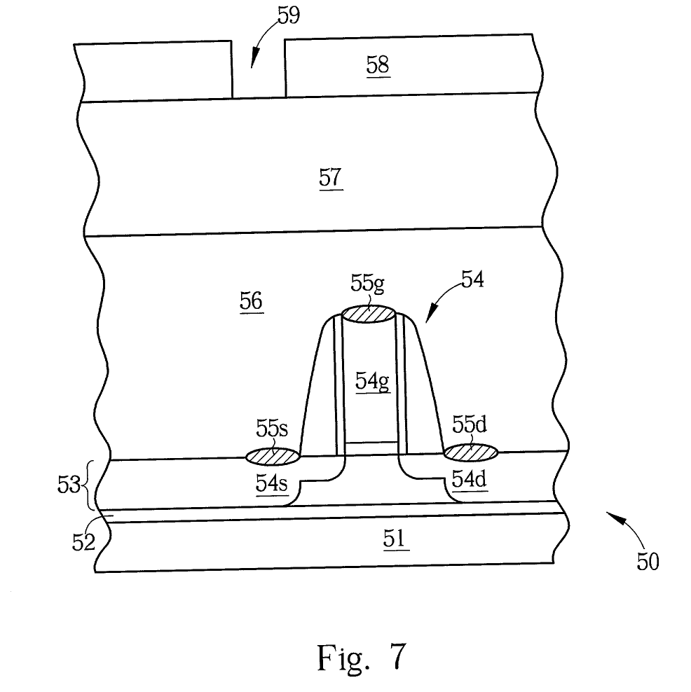

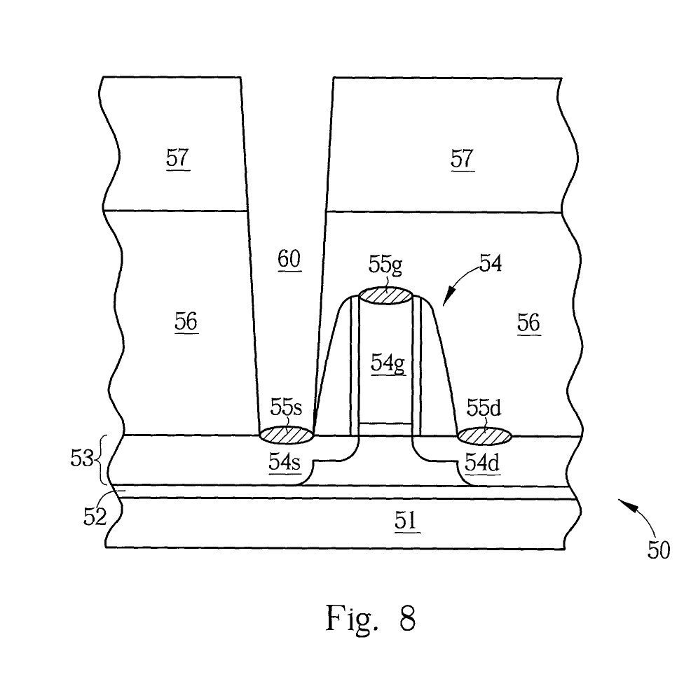

As shown in FIG. 7, a first photoresist layer 58 is evenly coated on the second ILD 57. A lithographic process is then performed so that the photoresist layer 58 comprises an opening 59 positioned on a predetermined area above the selective tungsten layers 55s, 55d, or 55g (in FIG. 7, the opening 59 is above the selective tungsten layer 55s) and extending down to the surface of the second ILD 57 to define the pattern of a Cu plug. As shown in FIG. 8, an anisotropic dry-etching process is performed along the opening 59 to vertically remove the first ILD 56 and the second ILD 57 beneath the opening 59 down to the selective tungsten layer 55s, so as to form a hole 60. Then, the photoresist layer 58 is completely removed by a resist stripping process.

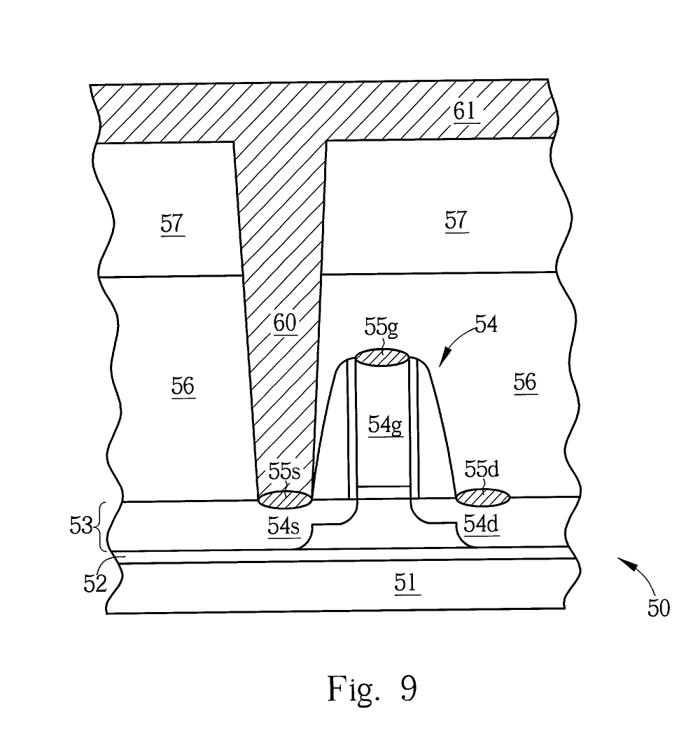

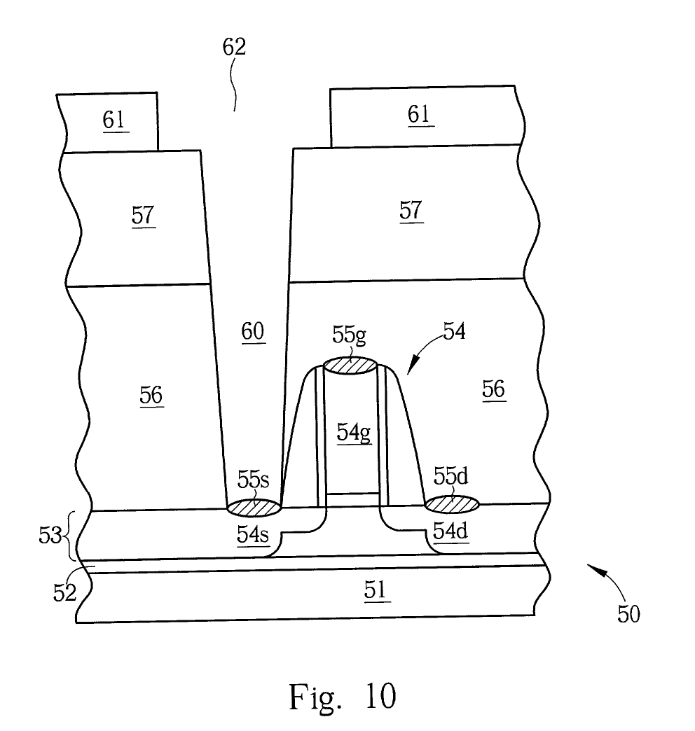

As shown in FIG. 9, another lithographic process is performed to coat a second photoresist layer 61 on the second ILD 57 and to fill the hole 60. Then, as shown in FIG. 10, an exposure and development process is performed so that the second photoresist layer 61 comprises a line-shaped opening 62 to define the patterns of connection to each device.

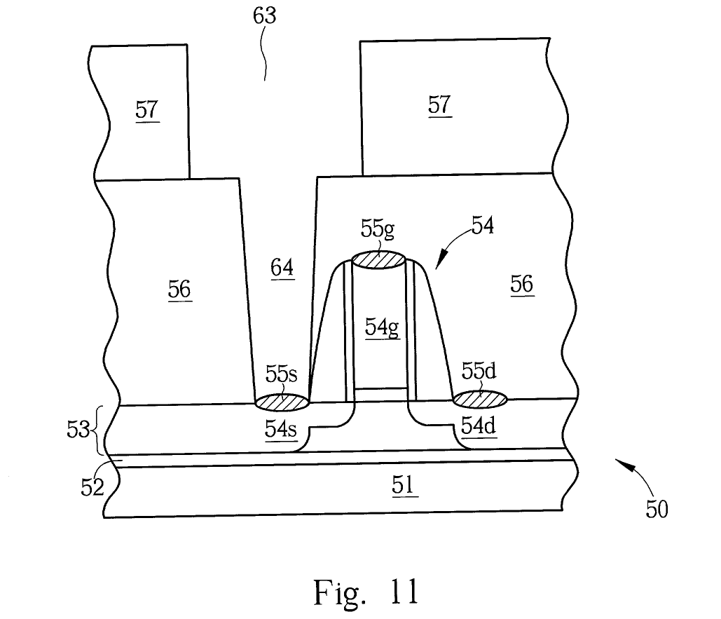

Then, as shown in FIG. 11, a second etching process is performed along the line-shaped opening 62 using a reactive ion etching (RIE) process, which uses a plasma comprised of fluorocarbon to remove the second ILD 57 beneath the line-shaped opening 62 down to the surface of the first ILD 56, so as to form a line-shaped trench 63. The hole 60 is shortened and becomes a plug hole 64. Next, the second photoresist layer 61 is completely removed.

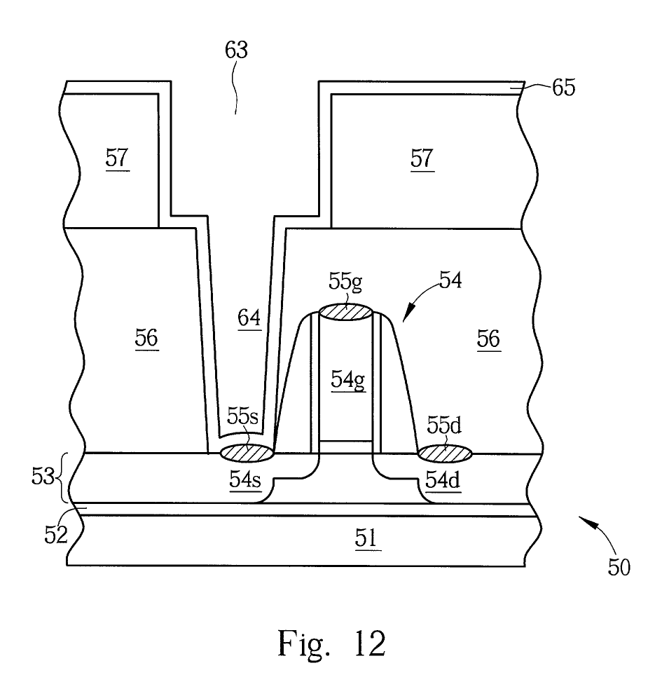

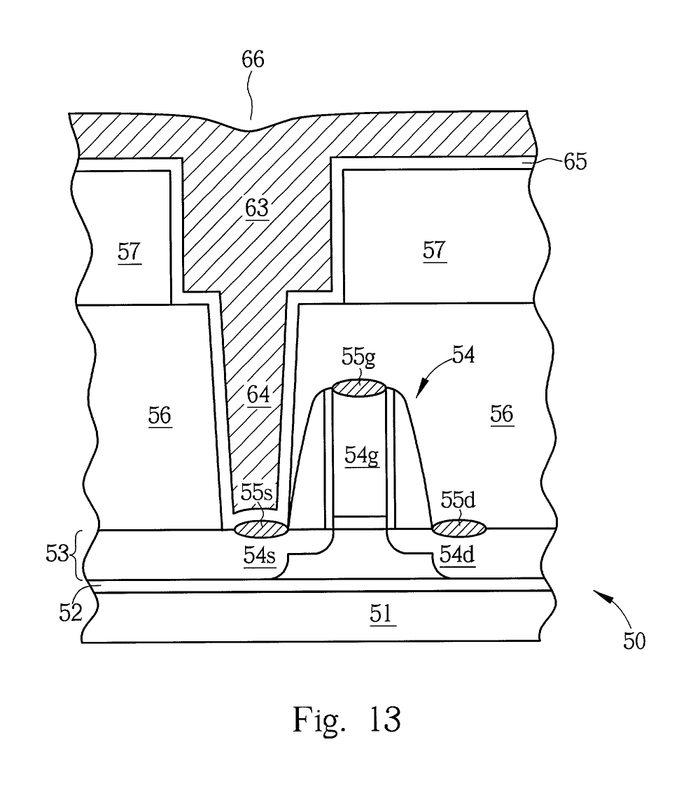

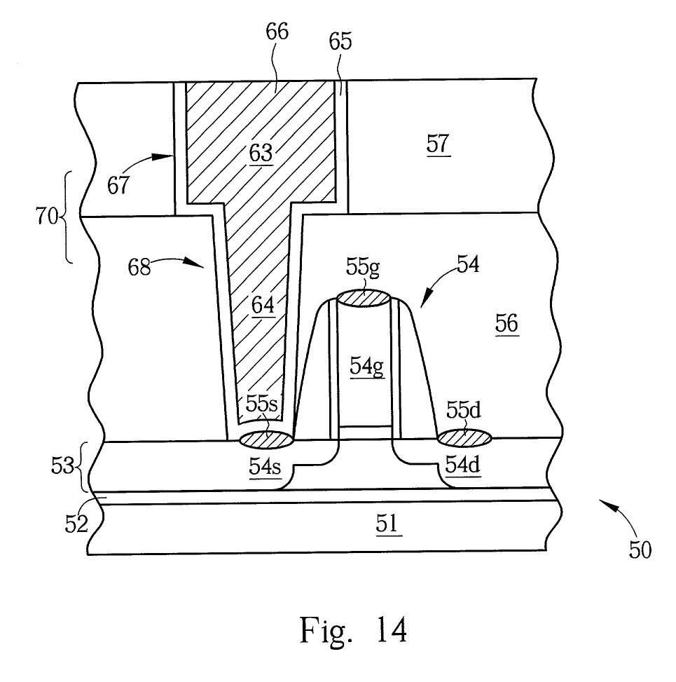

Please refer to FIG. 12. A diffusion barrier 65, comprised of a tantalum nitride (TaN)/tantalum (Ta) composite, is deposited on the surface of the line-shaped trench 63 and the plug hole 64. As shown in FIG. 13, a copper layer 66 is formed on the SOI substrate 50 to fill the line-shaped trench 63 and the plug hole 64. Referring to FIG. 14, a CMP process is performed to completely remove the copper layer 66 on the surface of the second ILD 57 so as to align the upper surface of the copper layer 66 in the line-shaped trench 63 with the surface of the second ILD 57. Then, both a Cu wire 67 and a Cu contact plug 68 are simultaneously formed, as shown in FIG. 14, to form a dual damascene Cu contact plug 70 to electrically connect the Cu wire 67 with the source 54s.

The second embodiment of the present invention is a so-called trench first damascene process, which first forms the Cu wire, followed by the Cu contact plug.

The third embodiment of the present invention is a self-aligned damascene process, which forms a silicon nitride (SiN) layer between the first ILD 56 and the second ILD 57 to function as a stop layer.

The characteristics of the present invention are:

(1) The present invention uses a diffusion barrier comprised of a TaN/Ta composite and a selective tungsten layer comprised of a WN/W composite to form a Cu contact plug on the first level (the surface of the silicon substrate) to prevent the diffusion of copper atoms into the underlying silicon substrate;

(2) The selective tungsten layer prevents not only the diffusion of copper atoms but also both leakage currents of the shallow junction and voids.

In contrast to the prior art, the present invention forms a Cu contact plug on the first level (the surface of the silicon substrate), and additionally, a selective tungsten layer is formed on the fully-depleted SOI substrate to prevent both leakage current and voids so as to obtain improved device performance.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A Cu contact plug using selective W deposition, with the Cu contact plug and a Cu wire simultaneously formed in a dual damascene structure of an inter-layer dielectric, to electrically connect the Cu wire with a source, drain, or gate electrode of a MOS transistor, wherein a layer of selective tungsten is formed between the Cu contact plug and the source, drain, or gate electrode to prevent the diffusion of copper atoms to the underlying silicon substrate.

2. The Cu contact plug of claim l wherein the selective tungsten layer is comprised of tungsten nitride (WN)/tungsten composite.

3. The Cu contact plug of claim 1 wherein the selective tungsten layer is selectively deposited on the source, drain, and gate electrode using a silicon reduction reaction.

4. The Cu contact plug of claim 1,wherein the MOS transistor is fabricated on a silicon-on-insulator (SOI) substrate, which comprises a supporting substrate, an insulating layer formed on the supporting substrate, and a silicon layer positioned on the insulating layer.

5. The Cu contact plug of claim 4 wherein the SOI substrate is a fully-depleted SOI substrate.

6. The Cu contact plug of claim 4 wherein the thickness of the silicon layer is approximately 0.1 to 0.3 micrometers.

7. The Cu contact plug of claim 1 further comprising a diffusion barrier formed between the Cu contact plug and the selective tungsten layer.

8. The Cu contact plug of claim 7 wherein the diffusion barrier is composed of tantalum nitride (TaN)/tantalum (Ta) composite.

9. A Cu contact plug for a MOS transistor fabricated on an SOI substrate, the MOS transistor having a selectively tungsten-deposited source, drain, and gate electrode electrically connected with a Cu wire by a Cu contact plug, wherein the Cu contact plug and the Cu wire are simultaneously formed in a dual damascene structure of an inter-layer dielectric.

10. The Cu contact plug of claim 9 wherein a selective tungsten layer selectively deposited on the source, drain, or gate electrode, is used to prevent the diffusion of copper atoms from the Cu contact plug to the underlying silicon substrate.

11. The Cu contact plug of claim 10 wherein the selective tungsten layer is composed of tungsten nitride (WN)/tungsten composite.

12. The Cu contact plug of claim 10 wherein the selective tungsten layer is selectively deposited on the source, drain, and gate electrode using a silicon reduction reaction.

13. The Cu contact plug of claim 9 wherein the SOI substrate is a fully-depleted SOI substrate.

14. The Cu contact plug of claim 9 further comprising a diffusion barrier formed between the Cu contact plug and the selective tungsten layer.

15. The Cu contact plug of claim 14 wherein the diffusion barrier is composed of tantalum nitride (TaN)/tantalum (Ta) composite.
